(19) United States
(12) Patent Application Publication
(10) Pub. No.: US 2020/0159071 A1
(43) Pub. Date: May 21, 2020

(54) BACK LIGHT UNIT AND DISPLAY DEVICE HAVING THE SAME

(71) Applicant: Samsung Display Co., Ltd., Yongin-si (KR)

(72) Inventor: Byung Seo YOON, Yongin-si (KR)

(21) Appl. No.: 16/598,683

(22) Filed: Oct. 10, 2019

(30) Foreign Application Priority Data
Nov. 21, 2018 (KR) 10-2018-0144570

(51) Int. Cl. G02F 1/1335; F21K 9/69; G02B 5/02; G02B 19/00; H01L 33/50

(52) U.S. Cl. CPC G02F 1/133606; F21K 9/69; G02F 1/133504; F21Y 2115/10; G02B 19/0061; H01L 33/50; G02B 5/0231

(57) ABSTRACT

A back light unit includes: a light emitting module including a substrate, a plurality of point light sources disposed on the substrate, and a plurality of optical lenses disposed to cover the respective point light sources; and an optical sheet disposed on the light emitting module to be in contact with at least some portions of the optical lenses.

### CROSS-REFERENCE TO RELATED APPLICATION

This application claims priority to and the benefit of Korean patent application 10-2018-0144570, filed on Nov. 21, 2018 in the Korean Intellectual Property Office, the entire disclosure of which is incorporated herein by reference.

### BACKGROUND

### 1. Field

The present disclosure generally relates to a display device, and, more particularly, to a back light unit and a display device having the same.

### 2. Related Art

In general, a display device includes a display panel for generating an image and a back light unit for supplying light to the display panel. The display panel displays an image by adjusting transmittance of light provided from the back light unit.

The back light unit can be classified as an edge type back light unit for supplying light to the display panel from an edge side of the display panel or a direct type back light unit for supplying light to the display panel at a back or rear side of the display panel.

The direct type back light unit has high light utilization efficiency, easy handling, no limitation in the size of the display panel, and relatively low price.

### SUMMARY

Aspects of embodiments are directed toward a direct type back light unit (direct back light unit) in which an optical sheet is disposed to be in contact with an optical lens of a light emitting module.

Aspects of embodiments are directed toward a display device having the direct type back light unit.

According to an embodiment of the present disclosure, there is provided a back light unit including: a light emitting module including a substrate, a plurality of point light sources disposed on the substrate, and a plurality of optical lenses disposed to cover the respective point light sources; and an optical sheet disposed on the light emitting module to be in contact with at least some portions of the optical lenses.

The optical sheet may include a diffusion layer in contact (e.g., direct contact) with portions of surfaces of at least some of the optical lenses.

Each of the optical lenses may include at least one projection formed to protrude from the surface of each of the optical lenses.

The at least one projection may be in contact with the diffusion layer.

A length of the at least one projection in a vertical direction may be 1 mm or less from a top surface at the center of each of the optical lenses.

A maximum length of the at least one projection in a horizontal direction may be 2 mm or less.

The optical sheet may further include: a prism layer disposed on the diffusion layer; and a protective layer disposed on the prism layer.

The optical sheet may further include: a first barrier layer disposed on the diffusion layer; and a light conversion layer disposed on the first barrier layer.

The light conversion layer may include a plurality of quantum dots for converting the wavelength of light.

The optical sheet may further include: a second barrier layer disposed on the light conversion layer; a prism layer disposed on the second barrier layer; and a protective layer disposed on the prism layer.

The light emitting module may further include a reflective layer disposed on the substrate, the reflective layer not overlapping with the optical lenses.

Each of the point light sources may include at least one light emitting diode.

According to an embodiment of the present disclosure, there is provided a display device including: an optical lens module including a plurality of point light sources and a plurality of optical lenses disposed to cover the respective point light sources; an optical sheet; and a display panel, the optical sheet being between the display panel and the optical lenses and in contact with at least some portions of the optical lenses.

The optical lens module and the optical sheet may constitute a direct type back light unit.

The optical sheet may include a diffusion layer in contact (e.g., direct contact) with portions of surfaces of at least some of the optical lenses.

Each of the optical lenses may include at least one projection formed to protrude from the surface of each of the optical lenses.

The at least one projection may be in contact with the diffusion layer.

The display panel may include: a first substrate disposed on the optical sheet; a second substrate disposed on the first substrate; and a liquid crystal layer interposed between the first substrate and the second substrate.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is an exploded perspective view schematically illustrating a display device according to an embodiment of the present disclosure.

FIG. 2A is a sectional view illustrating an example of the display device of FIG. 1.

FIG. 2B is a plan view illustrating an example of a light emitting module included in the display device of FIG. 2A.

FIG. 3 is a sectional view illustrating an example of a back light unit included in the display device of FIG. 1.

FIG. 4 is a sectional view illustrating an example of the back light unit included in the display device of FIG. 1.

FIG. 5 is a sectional view illustrating an example of the back light unit included in the display device of FIG. 1.

FIG. 6 is a sectional view illustrating an example of the back light unit included in the display device of FIG. 1.

### DETAILED DESCRIPTION

Hereinafter, exemplary embodiments are described in more detail with reference to the accompanying drawings so that those skilled in the art may easily practice the present disclosure. The present disclosure may be implemented in various different forms and is not limited to the exemplary embodiments described in the present specification.

Throughout the drawings, like components are designated by like reference numerals, and their overlapping descriptions may not be provided again.

In addition, the size and thickness of each component such as a layer or region, which is illustrated in the drawings, are merely shown for better understanding and ease of description, but the present disclosure is not limited thereto. Thicknesses of several portions and regions may be exaggerated for clear expression. The term “layer” used throughout the specification may include a film, a sheet, a plate, and the like, each of which has a constant width and thickness.

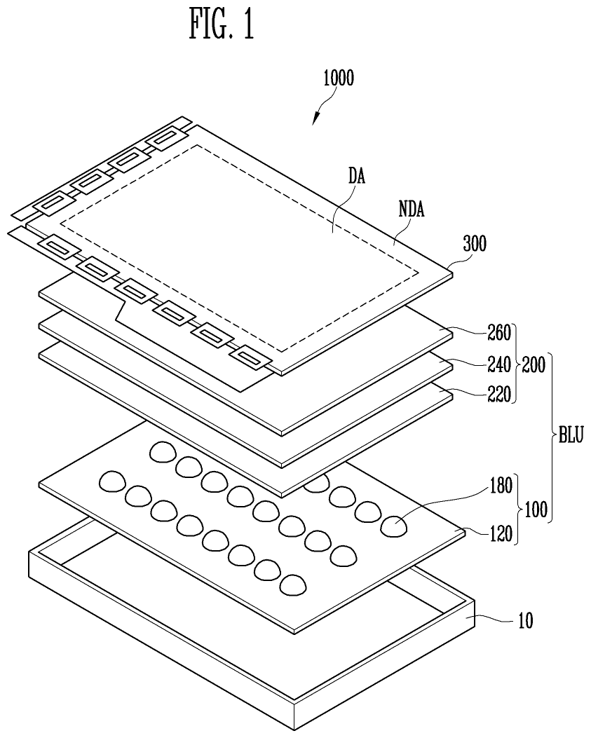

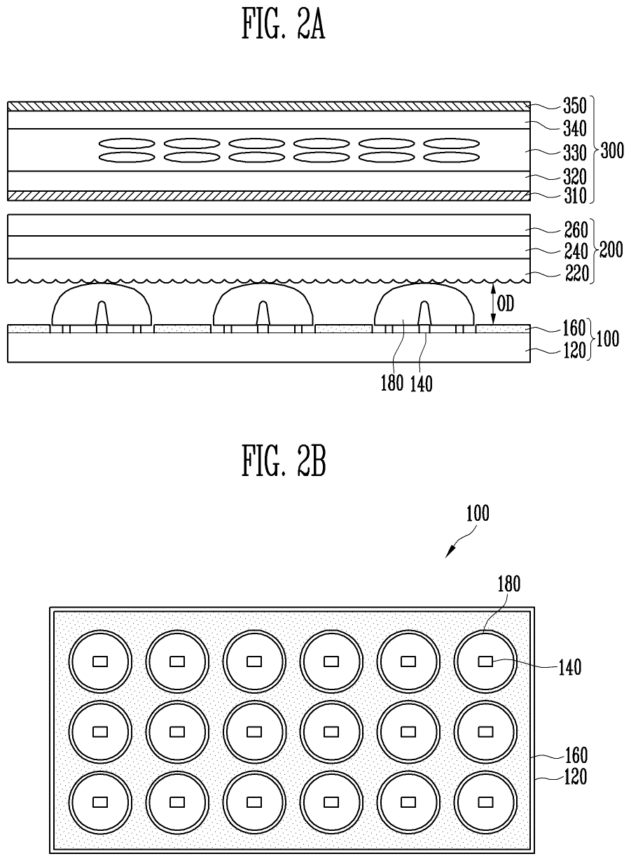

FIG. 1 is an exploded perspective view schematically illustrating a display device according to an embodiment of the present disclosure. FIG. 2A is a sectional view illustrating an example of the display device of FIG. 1. FIG. 2B is a plan view illustrating an example of a light emitting module included in the display device of FIG. 2A.

Referring to FIGS. 1 to 2B, a display device 1000 may include a back light unit BLU including a light emitting module 100 and an optical sheet 200, and a display panel 300.

The back light unit BLU may be configured such that a light source part, a plurality of optical elements, and a plurality of electrical elements are accommodated in a frame 10. The back light unit BLU may be a direct type back light unit (direct back light unit).

Specifically, the light source part may be configured with a plurality of point light sources. For example, a plurality of light emitting diode packages may be mounted on a substrate 120 that is a strip type printed circuit board at a set or predetermined distance, to form point light sources. The number of point light sources and light emitting diode packages may be changed depending on a size of the display panel 300, an output of light emitting diodes, a luminance required by the display device 1000, etc.

A white light emitting diode package emitting white light may be used as the point light source, or red, green, and blue light emitting diode packages that are combined and disposed with each other may be used as the point light source. The light emitting diode package may be a high intensity or ultra-high intensity light emitting diode package having a light emitting surface that is relatively large in size. The light emitting diode package may be, for example, a high color reproduction light emitting diode package emitting light of green and magenta.

In an embodiment, one light emitting diode package may include one or more light emitting diodes or light emitting diode chip. Hereinafter, the light emitting diode package will be described as a light emitting diode 140.

The light emitting module 100 may include the substrate 120, a plurality of point light sources that are disposed on the substrate 120 and are implemented with the light emitting diode 140, a reflective layer 160 disposed on the substrate 120, and an optical lens 180 disposed to cover the light emitting diode 140.

The reflective layer 160 reflects light emitted from the light emitting diode 140 and light reflected by the optical lens 180 or another structure, and allows the lights to finally advance toward the display panel 300, thereby improving light efficiency.

In an embodiment, a hole may be bored at a position of the reflective layer 160, at which the light emitting diode 140 and the optical lens 180 are located, so that the light emitting diode 140 and the optical lens 180 can be mounted on the substrate 120. For example, as shown in FIG. 2B, the reflective layer 160 does not overlap with the light emitting diode 140 and the optical lens 180.

The reflective layer 160 may be configured with one or more reflective layers. For example, the reflective layer 160 may be configured with a general reflective layer (such as a white reflective film) and/or a high reflexibility reflective layer (such as a silver reflective film).

The optical lens 180 is installed such that light emitted from the light emitting diode 140 that is a point light source is not concentrated above the light emitting surface of the light emitting diode 140 but can be uniformly dispersed through the entire display panel 300. The optical lens 180 applied to ensure the luminance uniformity of the entire display panel 300 is installed to cover the light emitting diode 140, and to refract and scatter light emitted from the light emitting diode 140.

In an embodiment, the number of optical lenses 180 may correspond to that of light emitting diodes 140 (i.e., light emitting diode packages), and the optical lenses 180 may be mounted on the substrate 120 to individually cover the light emitting diodes 140.

In an embodiment, the optical lens 180 may be attached to the substrate 120 through at least one leg extending downwardly from a bottom surface of the optical lens 180. For example, the optical lens 180 may be disposed to be spaced apart from each of the substrate 120 and the light emitting diode 140 at a set or predetermined distance.

The optical lens 180 may be formed of a transparent material such as polycarbonate (PC), polymethyl methacrylate (PMMA), and/or silicon.

The optical sheet 200 may be disposed on the optical lens 180. In an embodiment, the optical sheet 200 may be disposed to be in contact with at least portions of the optical lenses 180.

In an embodiment, the optical sheet 200 may include a diffusion layer 220, a prism layer 240, and a protective layer 260.

The diffusion layer 220 may diffuse light passing through the optical lens 180 to a surface light source emitting light having brightness more uniform than that of the light passing through the optical lens 180. In an embodiment, the diffusion layer 220 may include a plurality of irregular unevennesses at a bottom surface thereof, which is in contact with the optical lens 180. Light incident from the optical lens 180 may be diffused and scattered by the unevennesses.

In an embodiment, the diffusion layer 220 may be formed of an optically transparent resin such as polyethylene terephthalate (PET), polypropylene (PP), polycarbonate (PC), and/or polymethyl methacrylate (PMMA). Also, in an embodiment, the diffusion layer 220 may include a plurality of scattering particles therein. The scattering particles may be formed of acrylic resin, styrene resin, and/or the like.

At least a portion of the bottom surface of the diffusion layer 220 may be in direct contact with portions of surfaces of the optical lenses 180. Accordingly, the diffusion layer 220 may be supported by the plurality of optical lenses 180.

A related art direct type back light unit BLU has a structure in which separate supporting members are disposed around the optical lens 180 so as to secure an optical distance between the light emitting diode 140 and the diffusion layer 220. The supporting members are used to block or prevent movement of the diffusion layer 220 and support the diffusion layer 220. However, the supporting members have negative influence on the luminance uniformity of the back light unit BLU, and the optical sheet 200 including the diffusion layer 220 is not completely fixed onto the light emitting module 100, using only the supporting members.

The direct type back light unit BLU according to the embodiment of the present disclosure has a structure in which the optical lens 180 and the diffusion layer 220 are in direct contact with each other, so that the one or more optical lenses 180 can serve as supporting members. Thus, the optical sheet 200 including the diffusion layer 220 can be stably fixed, and the configuration of the supporting member can be removed. In addition, an air layer still exists between the diffusion layer 220 (having the unevennesses) and the optical lens (a layer of the optical lenses) 180, so that the optical lens 180 can stably perform light diffusion and scattering functions.

Further, a distance OD between the optical sheet 200 and the reflective layer 160 of the direct type back light unit BLU is decreased, so that the thickness of the direct type back light unit BLU and the display device 1000 having the same can be decreased. For example, the distance OD between the optical sheet 200 and the reflective layer 160 may be controlled to about 5 mm or less. Thus, the display device 1000 having the direct type back light unit BLU can be implemented to be relatively slim or thin in size.

The prism layer 240 may be disposed on the diffusion layer 220. The prism layer 240 is used to adjust an advancing direction of light equally diffused by the diffusion layer 220 and condense the light, thereby increasing the luminance of the light. For example, the prism layer 240 may include a plurality of prism layers including prisms extending in different directions.

The prism layer 240 may be formed of an optically transparent resin such as PET, PP, PC, and/or PMMA.

The protective layer 260 may protect the optical sheet from external impact or the introduction of a foreign substance. The protective layer 260 may be disposed on the prism layer 240.

In an embodiment, in order to improve light efficiency of the display device 1000, a reflective polarizing layer (also referred to as a “reflective polarizing film”), for converting a light component absorbed by a polarizing layer 310 of the display panel 300 into light transmitted through the polarizing layer 310 through polarized light selective reflection, may be located as the uppermost layer of the back light unit BLU.

The optical sheet 200 may not include some of the above-described individual layers 220, 240, and 260. In addition, some of the above-described individual layers 220, 240, and 260 included in the optical sheet 200 may be configured with a plurality of layers. Also, the optical sheet 200 may further include an optical layer having other suitable characteristics.

The display panel 300 may include a first substrate 320, a second substrate 340, and a liquid crystal layer 330 between the first substrate 320 and the second substrate 340. In an example, the display panel may be a liquid crystal display panel.

In an embodiment, the display panel 300 may include a first substrate 320 that provides a thin film transistor and a pixel electrode, a second substrate 340 that provides a common electrode and a color filter, and a liquid crystal layer 330 disposed between the first substrate 320 and the second substrate 340.

The display panel 300 may display a gray level of a grayscale by liquid crystal molecules rearranged along an electric field generated between the pixel electrode and the common electrode. The liquid crystal molecules included in the liquid crystal layer 330 may be driven in an In-Plane Switching (IPS) mode, a Plane to Line Switching (PLS) mode, a Fringe Field Switching (FFS) mode, or the like by the electric field generated between the pixel electrode and the common electrode.

In an embodiment, polarizing layers 310 and 350 may be respectively disposed on top and bottom surfaces of the display panel 300. For example, a first polarizing layer 310 may be disposed on a bottom surface of the first substrate 320, and a second polarizing layer 350 may be disposed on a top surface of the second substrate 340. In an embodiment, the first and second polarizing layers 310 and 350 may be provided in the form of a polarizing film.

However, this is merely illustrative, and the display device 1000 may have only one of the first and second polarizing layers 310 and 350.

In an embodiment, polarization axes of the first and second polarizing layers 310 and 350 may be orthogonal to each other.

As described above, the back light unit BLU and the display device 1000 having the same according to the embodiment of the present disclosure can have a structure in which the optical lens 180 and the diffusion layer 220 are in direct contact with each other. Thus, the thickness of the back light unit BLU and the display device 1000 having the same can be considerably decreased without deterioration of display quality.

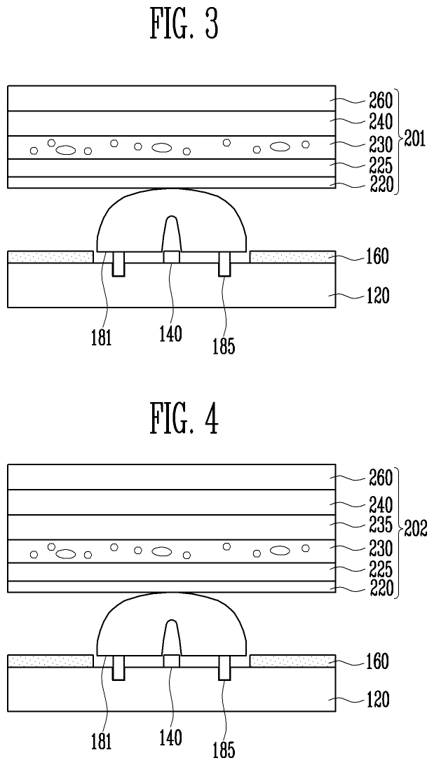

FIG. 3 is a sectional view illustrating an example of the back light unit included in the display device of FIG. 1.

The back light unit according to this embodiment is substantially identical to the back light unit shown in FIG. 2A except for a partial configuration of an optical sheet and a partial configuration of an optical lens. Therefore, components identical or corresponding to those of the back light unit shown in FIG. 2A are designated by like reference numerals, and their overlapping descriptions may not be provided again.

Referring to FIGS. 2A and 3, the back light unit BLU may include a light emitting module 100 and an optical sheet 201.

The light emitting module 100 may include a substrate 120, a plurality of point light sources that are disposed on the substrate 120 and are implemented with a light emitting diode 140, a reflective layer 160 disposed on the substrate 120, and an optical lens 181 disposed to cover the light emitting diode 140.

In an embodiment, the substrate 120 may include a recess into which a leg 185 of the optical lens 181 is inserted. The optical lens 181 includes at least one leg 185 extending downwardly from a bottom surface thereof. The leg 185 of the optical lens 181 may be inserted into the recess of the substrate 120. Accordingly, the optical lens 181 can be stably fixed.

The optical sheet 210 may include a diffusion layer 220, a first barrier layer 225 disposed on the diffusion layer 220, and a light conversion layer 230 disposed on the first barrier layer 225.

A bottom surface of the diffusion layer 220 may be in contact with the optical lens 181. The diffusion layer 220 may include a plurality of irregular unevennesses at its bottom surface in contact with the optical lens 181.

The barrier layer 225 may block the introduction of gas such as oxygen and moisture into the light conversion layer 230. The first barrier layer 225 may include polymer, glass, and/or a dielectric material. For example, the first barrier layer 225 may include a polymer and/or an oxide (such as silicon oxide, titanium oxide, and/or aluminum oxide), but the present disclosure is not limited thereto.

The light conversion layer 230 may include a plurality of quantum dots for converting the wavelength of light. The quantum dots change the wavelength band of light, and combine light having different wavelength bands and then emit the combined light. The quantum dots generate light having a short wavelength when the size of the quantum dot decreases, and generate light having a long wavelength when the size of the quantum dot increases.

A wavelength conversion layer may include quantum dots having various suitable sizes, and, accordingly, lights having various suitable wavelength bands may be emitted from the light conversion layer 230.

In an embodiment, the light radiated from the light conversion layer 230 may be white light. Specifically, the light emitted from the light emitting diode 140 may be blue light. The blue light may be converted into the white light by the quantum dots of the light conversion layer 230. However, this is merely illustrative, and the light emitted from the light emitting diode 140 and the light radiated from the light conversion layer 230 are not limited thereto.

A prism layer 240 and a protective layer 260 may be sequentially disposed on the light conversion layer 230.

FIG. 4 is a sectional view illustrating an example of the back light unit included in the display device of FIG. 1.

The back light unit according to this embodiment is substantially identical to the back light unit shown in FIG. 3 except for a partial configuration of an optical sheet. Therefore, components identical or corresponding to those of the back light unit shown in FIG. 3 are designated by like reference numerals, and their overlapping descriptions may not be provided again.

Referring to FIGS. 3 and 4, the back light unit BLU may include a light emitting module 100 and an optical sheet 202.

As compared with the optical sheet 201 of FIG. 3, the optical sheet 202 may further include a second barrier layer 235 disposed between the light conversion layer 230 and the prism layer 240.

The second barrier layer 235 may block the introduction of gas such as oxygen and moisture into the light conversion layer 230. The second barrier layer 235 may include the substantially same material as the first barrier 225.

FIG. 5 is a sectional view illustrating an example of the back light unit included in the display device of FIG. 1.

The back light unit according to this embodiment is substantially identical to the back light unit shown in FIG. 2A except for a partial configuration of an optical lens. Therefore, components identical or corresponding to those of the back light unit shown in FIG. 2A are designated by like reference numerals, and their overlapping descriptions may not be provided again.

Referring to FIGS. 2A and 5, the direct type back light unit BLU may include a light emitting module 100 and an optical sheet 200.

The light emitting module 100 may include a substrate 120, a plurality of point light sources that are disposed on the substrate 120 and are implemented with a light emitting diode 140, a reflective layer 160 disposed on the substrate 120, and an optical lens 182 disposed to cover the light emitting diode 140.

In an embodiment, the optical lens 182 may include at least one projection PR formed to protrude upward from a surface of the optical lens 182. The projection PR may protrude toward the optical sheet 200 from a top surface of the optical lens 182. The projection PR may be in contact with a diffusion layer 220.

The projection PR may be integrally formed with the optical lens 182 in a manufacturing process of the optical lens 182. For example, the optical lens 182 having the projection PR may be formed from a mold having a shape in which a portion of a convex lens protrudes.

Although a case where two projections PR are formed at the optical lens 182 is illustrated in FIG. 5, the number of projections is not limited thereto.

The projections PR may be in direct contact with the diffusion layer 220, and support and fix the optical sheet 200 including the diffusion layer 220. Accordingly, the optical sheet 200 can be stably supported and fixed as compared with a structure in which a separate supporting member is disposed to fix the optical sheet 200.

In an embodiment, a length L2 of the projection PR in a vertical direction (a normal or longitudinal direction) DR2 may be 1 mm or less from the top surface at the center of the optical lens 182. The top surface at the center of the optical lens 182 may be spaced apart from the diffusion layer 220 by the projection PR. Accordingly, an air layer having a refractive index different from those of the optical lens 182 and the diffusion layer 220 is located between the optical lens 182 and the diffusion layer 220, so that light directed toward the display panel 300 from the optical lens 182 can be more widely diffused.

In an embodiment, a maximum length L1 of the projection PR in a horizontal direction (a latitudinal direction) DR1 may be about 2 mm or less. For example, when the projection PR has a cylindrical shape, the maximum diameter of the projection PR in the horizontal direction DR1 may be about 2 mm.

However, this is merely illustrative, and the number, shape, size, and positions of projections PR are not limited thereto. For example, a luminance variation caused by the projection PR and a position and a size of the projection PR may be determined such that the projection PR is not viewed.

As described above, the back light unit BLU and the display device 1000 having the same according to the embodiment of the present disclosure may include the optical lens 182 including the projection PR and the diffusion layer 220 in direct contact with the optical lens 182. Accordingly, the optical sheet 200 can be more stably supported by and fixed to the plurality of projections PR, and an unnecessary supporting member can be removed. Further, light directed toward the diffusion layer 220 from the optical lens 182 can be more widely diffused by the projection PR.

In addition, a distance OD1 between the optical sheet 200 and the reflective layer 160 of the direct type back light unit BLU is decreased, so that the thickness of the direct type back light unit BLU and the display device 1000 having the same can be considerably decreased.

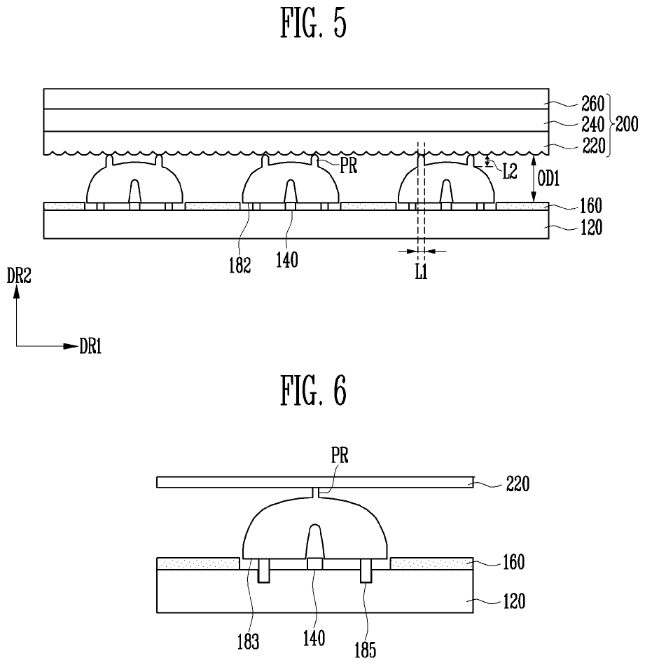

FIG. 6 is a sectional view illustrating an example of the back light unit included in the display device of FIG. 1.

The back light unit according to this embodiment is substantially identical to the back light unit shown in FIG. 5 except for a partial configuration of an optical lens. Therefore, components identical or corresponding to those of the back light unit shown in FIG. 5 are designated by like reference numerals, and their overlapping descriptions may not be provided again.

Referring to FIGS. 5 and 6, the direct type back light unit BLU may include a light emitting module 200.

In an embodiment, an optical lens 183 may include at least one projection PR formed to protrude upward from a surface thereof. The projection PR may protrude toward the optical sheet 200 from a top surface of the optical lens 183. The projection PR may be in contact with a diffusion layer 220.

As shown in FIG. 6, the optical lens 183 may include a projection PR that is formed at the center of the top surface thereof to be in contact with the diffusion layer 220. The projection PR may be in direct contact with the diffusion layer 220, and support and fix the optical sheet 200 including the diffusion layer 220. Accordingly, the optical sheet 200 can be stably supported and fixed as compared with a structure in which a separate supporting member is disposed to fix the optical sheet 200. Further, light directed toward the diffusion layer 220 from the optical lens 183 can be more widely diffused by the projection PR.

In addition, the distance between the optical sheet 200 and the reflective layer 160 of the direct type back light unit BLU is decreased, so that the thickness of the direct type back light unit BLU and the display device 1000 having the same can be considerably decreased.

According to the present disclosure, the back light unit and the display device having the same can have a direct type back light unit structure in which the optical sheet including the optical lens is in direct contact with the diffusion layer. Accordingly, the optical sheet is more stably supported by and fixed to the light emitting module, so that an unnecessary supporting member can be removed.

Further, the distance between the optical sheet and the reflective layer of the direct type back light unit can be decreased, and uniform back light having high intensity can be output. Thus, the thickness of the direct type back light unit and the display device having the same can be considerably decreased, and the output of back light having high quality can be ensured.

It will be understood that when an element or layer is referred to as being “on,” “connected to,” “coupled to,” or “adjacent to” another element or layer, it can be directly on, connected to, coupled to, or adjacent to the other element or layer, or one or more intervening elements or layers may be present. In contrast, when an element or layer is referred to as being “directly on,” “directly connected to,” “directly coupled to,” or “immediately adjacent to” another element or layer, there are no intervening elements or layers present.

The use of “may” when describing embodiments of the inventive concept refers to “one or more embodiments of the inventive concept.”

As used herein, the terms “substantially,” “about,” and similar terms are used as terms of approximation and not as terms of degree, and are intended to account for the inherent deviations in measured or calculated values that would be recognized by those of ordinary skill in the art. Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

As used herein, the terms “use,” “using,” and “used” may be considered synonymous with the terms “utilize,” “utilizing,” and “utilized,” respectively.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims and equivalents thereof.

What is claimed is:

1. A back light unit comprising:
a light emitting module comprising a substrate, a plurality of point light sources on the substrate, and a plurality of optical lenses disposed to cover the respective point light sources; and
an optical sheet on the light emitting module to be in contact with at least some portions of the optical lenses.

2. The back light unit of claim 1, wherein the optical sheet comprises a diffusion layer in contact with portions of surfaces of at least some of the optical lenses.

3. The back light unit of claim 2, wherein each of the optical lenses comprises at least one projection protruding from the surface of each of the optical lenses.

4. The back light unit of claim 3, wherein the at least one projection is in contact with the diffusion layer.

5. The back light unit of claim 3, wherein a length of the at least one projection in a vertical direction is about 1 mm or less from a top surface at a center of each of the optical lenses.

6. The back light unit of claim 3, wherein a maximum length of the at least one projection in a horizontal direction is about 2 mm or less.

7. The back light unit of claim 2, wherein the optical sheet further comprises:
a prism layer on the diffusion layer; and
a protective layer on the prism layer.

8. The back light unit of claim 2, wherein the optical sheet further comprises:
a first barrier layer on the diffusion layer; and
a light conversion layer on the first barrier layer.

9. The back light unit of claim 8, wherein the light conversion layer comprises a plurality of quantum dots to convert the wavelength of light.

10. The back light unit of claim 8, wherein the optical sheet further comprises:
a second barrier layer on the light conversion layer;
a prism layer on the second barrier layer; and
a protective layer on the prism layer.

11. The back light unit of claim 1, wherein the light emitting module further comprises a reflective layer on the substrate, the reflective layer not overlapping with the optical lenses.

12. The back light unit of claim 1, wherein each of the point light sources comprises at least one light emitting diode.

13. A display device comprising:
an optical lens module comprising a plurality of point light sources and a plurality of optical lenses disposed to cover the respective point light sources;
an optical sheet; and
a display panel,
the optical sheet being between the display panel and the optical lenses and in contact with at least some portions of the optical lenses.

14. The display device of claim 13, wherein the optical lens module and the optical sheet constitute a direct type back light unit.

15. The display device of claim 13, wherein the optical sheet comprises a diffusion layer in contact with portions of surfaces of at least some of the optical lenses.

16. The display device of claim 15, wherein each of the optical lenses comprises at least one projection protruding from the surface of each of the optical lenses.

17. The display device of claim 16, wherein the at least one projection is in contact with the diffusion layer.

18. The display device of claim 13, wherein the display panel comprises:
a first substrate on the optical sheet;
a second substrate on the first substrate; and
a liquid crystal layer between the first substrate and the second substrate.

19. A method of forming a back light unit, the method comprising:
providing both the light emitting module and the optical sheet in accordance with claim 1; and
contacting the optical sheet to at least some portions of the optical lenses of the light emitting module.

20. A method of forming a display device, the method comprising:
providing both the optical lens module and the optical sheet in accordance with claim 13;
contacting the optical sheet to at least some portions of the optical lenses of the optical lens module; and
arranging a display panel on the optical sheet.
